(19) United States
(12) Patent Application Publication
(10) Pub. No.: US 2020/0091194 A1
(43) Pub. Date: Mar. 19, 2020

(54) DISPLAY SUBSTRATE, METHOD FOR PREPARING THE SAME, AND DISPLAY DEVICE

(71) Applicants: BEIJING BOE TECHNOLOGY DEVELOPMENT CO., LTD., Beijing (CN); BOE TECHNOLOGY GROUP CO., LTD., Beijing (CN)

(72) Inventor: Hongfei CHENG, Beijing (CN)

(73) Assignees: BEIJING BOE TECHNOLOGY DEVELOPMENT CO., LTD., Beijing (CN); BOE TECHNOLOGY GROUP CO., LTD., Beijing (CN)

(21) Appl. No.: 16/422,074

(22) Filed: May 24, 2019

(30) Foreign Application Priority Data
Sep. 17, 2018 (CN) 201811081083.6

(51) Int. Cl. H01L 27/12

(52) U.S. Cl. CPC H01L 27/124; H01L 29/45; H01L 27/1248; H01L 27/1259

(57) ABSTRACT

The present disclosure provides a display substrate, a method for preparing the same, and a display device. The display substrate includes a driving thin-film transistor and a pixel electrode, in which a drain of the driving thin-film transistor is electrically connected to the pixel electrode through a conductive pattern made of a metal having a chemical activity weaker than Cu.

### CROSS-REFERENCE TO RELATED APPLICATION

This application claims priority to Chinese Patent Application No. 201811081083.6 filed on Sep. 17, 2018, which is incorporated herein by reference in its entirety.

### TECHNICAL FIELD

The present disclosure relates to the field of display technology, in particular to a display substrate, a method for preparing the same, and a display device.

### BACKGROUND

In the related art, the pixel electrode is usually prepared with ITO, and the drain electrode is prepared with Cu. The oxygen atoms in the pixel electrode combine with the Cu in the drain electrode to form copper oxide on the surface of the drain electrode. Since the copper oxide is non-conductive, this will reduce the reliability of the connection between the pixel electrode and drain electrode, thereby affecting the display quality of the display device.

### SUMMARY

In one aspect, an embodiment of the present disclosure provides a display substrate, including a driving thin-film transistor and a pixel electrode, in which a drain electrode of the driving thin-film transistor is electrically connected to the pixel electrode through a conductive pattern made of a metal having a chemical activity weaker than Cu.

Optionally, the drain electrode is not in direct contact with the pixel electrode.

Optionally, an insulating layer is arranged between the drain electrode and the conductive pattern, with the drain electrode being connected to the conductive pattern through a via hole penetrating through the insulating layer; and/or an insulating layer is arranged between the pixel electrode and the conductive pattern, with the pixel electrode being connected to the conductive pattern through a via hole penetrating through the insulating layer.

Optionally, the conductive pattern is made of Mo or Ti.

Optionally, the conductive pattern and a common electrode line of the display substrate are made of a same material and arranged in a same layer.

Optionally, the common electrode line and a data line of the display substrate extend in a same direction, and an orthogonal projection of the common electrode line on a base substrate of the display substrate at least partially overlaps an orthogonal projection of the data line on the base substrate.

Optionally, an organic insulating layer is arranged between the data line and the common electrode line.

Optionally, the organic insulating layer has a thickness of 1 μm to 2 μm.

In one example, a passivation layer and an overcoat are arranged between the common electrode line and the data line.

Optionally, the overcoat is made of an organic resin.

An embodiment of the present disclosure further provides a display device including the display substrate as described above.

An embodiment of the present disclosure further provides a method for manufacturing a display substrate including a driving thin-film transistor and a pixel electrode, including: forming a drain electrode of the driving thin-film transistor and the pixel electrode; and forming a conductive pattern by a metal having a chemical activity weaker than Cu, such that the drain electrode is electrically connected to the pixel electrode through the conductive pattern.

Optionally, the conductive pattern and a common electrode line of the display substrate are formed by a single patterning process.

### BRIEF DESCRIPTION OF THE DRAWINGS

FIG. 1 is a schematic plan view of a display substrate in the related art.

FIG. 2 is a schematic cross-sectional view along AA′ of the display substrate in FIG. 1.

FIG. 3 is a schematic cross-sectional view along BB′ of the display substrate in FIG. 1.

FIG. 4 is a schematic plan view of a display substrate according to an embodiment of the present disclosure.

FIG. 5 is a schematic cross-sectional view along AA′ of the display substrate in FIG. 4.

FIG. 6 is a schematic cross-sectional view along CC′ of the display substrate in FIG. 4.

### DETAILED DESCRIPTION

In order to make the technical problems to be solved, the technical solutions, and the advantages of the embodiments of the present disclosure more clearly, the present disclosure will be described hereinafter in conjunction with the drawings and specific examples.

The display substrate includes: a driving thin-film transistor, a pixel electrode and a common electrode, in which an insulating layer is arranged between the pixel electrode and the drain electrode of the driving thin-film transistor, and the pixel electrode is connected to the drain electrode through a via hole penetrating through the insulating layer.

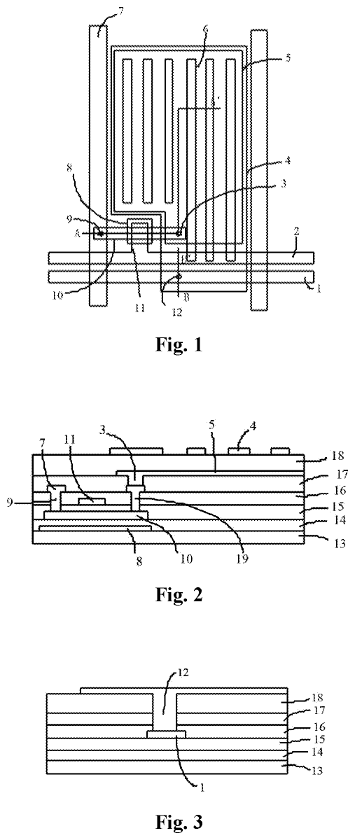

FIG. 1 is a schematic plan view of a display substrate in the related art. FIG. 2 is a schematic cross-sectional view along AA′ of the display substrate as shown in FIG. 1. FIG. 3 is a schematic cross-sectional view along BB′ of the display substrate as shown in FIG. 1. As shown in FIGS. 1 to 3, the display substrate in the related art includes: a shield layer 8 arranged on the base substrate 13; a first insulating layer 14 arranged on the shield layer 8; an active layer 10 arranged on the first insulating layer 14; a gate insulating layer 15 arranged on the active layer 10; a gate electrode 11 arranged on the gate insulating layer 15; an interlayer insulating layer 16 arranged on the gate electrode 11; a source electrode and a drain electrode arranged on the interlayer insulating layer 16, in which the source electrode is integrally arranged with the data line 7, the source electrode is connected to the active layer 10 through a first via hole 9, and the drain electrode is connected to the active layer 10 through a fourth via hole 19; a passivation layer 17 arranged on the source electrode and the drain electrode; a pixel electrode 5 arranged on the passivation layer 17, in which the pixel electrode 5 is connected to the drain electrode through a second via hole 3; a second insulating layer 18 arranged on the pixel electrode 5; a common electrode 4 arranged on the second insulating layer 18, in which a common electrode slit 6 is arranged between common electrodes 4, and the common electrode 4 is connected to the common electrode line 1 through a third via hole 12; a gate line 2 is arranged parallel to and in the same layer as the common electrode line 1, in which the data line 7 is perpendicular to the gate line 2 and the common electrode line 1.

In the related art, the pixel electrode 5 is usually made of ITO, and the drain electrode is made of Cu. Since the pixel electrode 5 is in direct contact with the drain electrode, the oxygen atoms in the pixel electrode combine with the Cu in the drain electrode to form copper oxide on the surface of the drain electrode. Since the copper oxide is non-conductive, this will reduce the reliability of the connection between the pixel electrode 5 and drain electrode, thereby affecting the display quality of the display device.

In order to solve the above problems, an embodiment of the present invention provide a display substrate, a method for preparing the same, and a display device, which are capable of ensuring the reliability of the connection between the pixel electrode and the drain electrode, and improving the display quality of the display device.

An embodiment of the present disclosure provides a display substrate, including a driving thin-film transistor and a pixel electrode, in which a drain electrode of the driving thin-film transistor is not in contact with the pixel electrode and the drain electrode is electrically connected to the pixel electrode through a conductive pattern made of a metal having a chemical activity weaker than Cu.

In this embodiment, the drain electrode of the driving thin-film transistor is not in direct contact with the pixel electrode. Thus, when the pixel electrode is prepared with ITO and the drain electrode is prepared with a metal such as Cu or Al which is easily oxidized, since the ITO is not in direct contact with the drain electrode, it is capable of preventing from forming an oxide on the surface of the drain electrode, and ensuring the reliability of the connection between the pixel electrode and the drain electrode, thereby improving the display quality of the display device.

Since Cu is easily oxidized when it is in contact with ITO, in order to prevent oxidation of the conductive pattern when it is in contact with the pixel electrode, the conductive pattern is prepared with a metal having a chemical activity weaker than Cu, e.g., it may be prepared with Mo or Ti. Mo and Ti have relatively stable properties, and do not form an oxide when being in contact with ITO.

Optionally, an insulating layer is arranged between the drain electrode and the conductive pattern, with the drain electrode being connected to the conductive pattern through a via hole penetrating through the insulating layer, that is, the conductive pattern is arranged in a different layer from that of the drain electrode; or, an insulating layer is arranged between the pixel electrode and the conductive pattern, with the pixel electrode being connected to the conductive pattern through a via hole penetrating through the insulating layer, that is, the conductive pattern is arranged in a different layer from that of the pixel electrode.

Optionally, an insulating layer is arranged between the drain electrode and the conductive pattern, with the drain electrode being connected to the conductive pattern through a via hole penetrating through the insulating layer; and an insulating layer is arranged between the pixel electrode and the conductive pattern, with the pixel electrode being connected to the conductive pattern through a via hole penetrating through the insulating layer, that is, both the pixel electrode and the drain electrode are arranged in different layers from that of the conductive pattern.

Optionally, the conductive pattern may be made of a same material and arranged in a same layer as those of other film layer pattern of the display substrate, such that the conductive pattern and other film layer patterns of the display substrate can be simultaneously formed by a single patterning process, and thus a conductive pattern is formed without increasing the number of times of patterning the display substrate.

For example, the conductive pattern may be arranged in the same layer as that of the common electrode line of the display substrate, such that the conductive pattern and the common electrode line may be simultaneously formed by a single patterning process.

Further, the common electrode line and a data line of the display substrate extend in a same direction, and an orthogonal projection of the common electrode line on a base substrate of the display substrate at least partially overlaps an orthogonal projection of the data line on the base substrate, which may improve the transmittance of the display substrate. Optionally, the orthogonal projection of the common electrode line on the base substrate completely overlaps with the orthogonal projection of the data line on the base substrate.

A common voltage signal is transmitted on the common electrode line. In order to prevent the electrical signal transmitted on the common electrode line from affecting the data voltage signal transmitted on the data line, the distance between the common electrode line and the data line should be relatively far. Optionally, an organic insulating layer is arranged between the data line and the common electrode line. The thickness of the organic insulating layer is generally relatively large, such that the distance between the data line and the common electrode line is relatively far. For example, the organic insulating layer may have a thickness of 1 μm to 2 μm.

Embodiments of the present disclosure have the following advantageous effects.

In the above solution, the drain electrode of the driving thin-film transistor is not in direct contact with the pixel electrode. Thus, when the pixel electrode is prepared with ITO and the drain electrode is prepared with a metal such as Cu or Al which is easily oxidized, since the ITO is not in direct contact with the drain electrode, it is capable of preventing from forming an oxide on the surface of the drain electrode, and ensuring the reliability of the connection between the pixel electrode and the drain electrode, thereby improving the display quality of the display device.

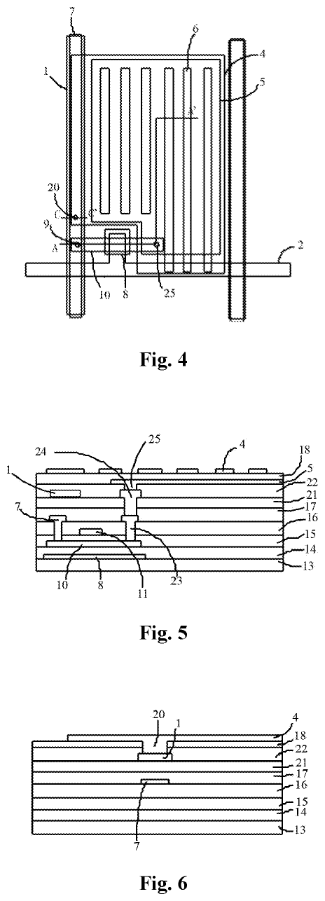

FIG. 4 is a schematic plan view of a display substrate according to an embodiment of the present disclosure; FIG. 5 is a schematic cross-sectional view along AA′ of the display substrate as shown in FIG. 4; and FIG. 6 is a schematic cross-sectional view along BB′ of the display substrate as shown in FIG. 4. As shown in FIGS. 4 to 6, the display substrate according to an embodiment of the present disclosure includes: a shield layer 8 arranged on the base substrate 13; a first insulating layer 14 arranged on the shield layer 8; an active layer 10 arranged on the first insulating layer 14; a gate insulating layer 15 arranged on the active layer 10; a gate electrode 11 arranged on the gate insulating layer 15; an interlayer insulating layer 16 arranged on the gate electrode 11; a source electrode and a drain electrode 23 arranged on the interlayer insulating layer 16, in which the source electrode is integrally arranged with the data line 7, the source electrode is connected to the active layer 10 through a via hole 9, and the drain electrode 23 is connected to the active layer 10 through a via hole; a passivation layer 17 arranged on the source electrode and the drain electrode; an overcoat 21 arranged on the passivation layer 17, in which the overcoat 21 may be made of an organic resin, that is, the above-mentioned organic insulating layer; a conductive pattern 24 arranged on the overcoat 21, in which the conductive pattern 24 is made of a same material and arranged in the same layer as that of the common electrode line 1, and the conductive pattern 24 is arranged in connected to the drain electrode 23 through a via hole; a third insulating layer 22 arranged on the conductive pattern 24; and a pixel electrode 5 arranged on the third insulating layer 22, in which the pixel electrode 5 is connected to the conductive pattern 24 through a sixth via hole 25; a second insulating layer 18 arranged on the pixel electrode 5; and a common electrode 4 arranged on the second insulating layer 18, in which a common electrode slit 6 is arranged between the common electrodes 4, and the common electrode 4 is connected to the common electrode line 1 through a fifth via hole 20.

In this embodiment, the data line 7 is parallel to the common electrode line 1, and is arranged in a different layer. The common electrode line 1 is arranged above the data line 7, and is arranged in the same layer as that of the conductive pattern 24. An orthogonal projection of the common electrode line 1 on the base substrate 13 at least partially overlaps with an orthogonal projection of the data line 7 on the base substrate 13.

In this embodiment, the common electrode line 1 may be prepared with a metal material, such as Mo or Ti, and the conductive pattern 24 may also be prepared with the metal material, such as Mo or Ti. Mo and Ti have relatively stable properties, and do not form an oxide when being in contact with ITO.

The data line 7, the drain electrode 23, and the source electrode may be prepared with a metal material, such as Cu or Al.

The gate line 2 and the gate electrode 11 may be prepared with a metal material, such as Cu, Al, Mo, Ti, Cr, and W, or may be prepared with an alloy of these materials.

In this embodiment, the gate insulating layer 15 may be prepared with silicon nitride or silicon oxide. The gate insulating layer 15 may be of a single-layer structure or a multilayer structure, such as a stacked structure of silicon oxide and silicon nitride.

In this embodiment, the interlayer insulating layer 16 may be prepared with silicon nitride or silicon oxide. The interlayer insulating layer 16 may be of a single-layer structure or a multilayer structure, such as a stacked structure of silicon oxide and silicon nitride.

In this embodiment, the passivation layer 17 may be prepared with silicon nitride or silicon oxide. The passivation layer 17 may be of a single-layer structure or a multilayer structure, such as a stacked structure of silicon oxide and silicon nitride.

In this embodiment, the first insulating layer 14 may be prepared with silicon nitride or silicon oxide. The first insulating layer 14 may be of a single-layer structure or a multilayer structure, such as a stacked structure of silicon oxide and silicon nitride.

In this embodiment, the second insulating layer 18 may be prepared with silicon nitride or silicon oxide. The second insulating layer 18 may be of a single-layer structure or a multilayer structure, such as a stacked structure of silicon oxide and silicon nitride.

In this embodiment, the third insulating layer 22 may be prepared with silicon nitride or silicon oxide. The third insulating layer 22 may be of a single-layer structure or a multilayer structure, such as a stacked structure of silicon oxide and silicon nitride.

In this embodiment, the active layer 10 may be prepared with amorphous silicon, polycrystalline silicon, or a metal oxide semiconductor material.

In this embodiment, the common electrode line 1 and the data line 7 are separated by a passivation layer 17 and an overcoat 21, so that the distance between the data line 7 and the common electrode line 1 is relatively far, and the effect of the electrical signal transmitted on the common electrode line 1 on the data voltage signal transmitted on data line 7 is reduced.

An embodiment of the present disclosure further provides a display device including the display substrate as described above. The display device may include any product or component having a display function, such as a television, a display, a digital photo frame, a mobile phone, and a tablet computer. The display device further includes a flexible circuit board, a printed circuit board, and a backplane.

The embodiment of the present disclosure further provides a method for manufacturing a display substrate including a driving thin-film transistor and a pixel electrode, including: forming a drain electrode of the driving thin-film transistor and the pixel electrode; and forming a conductive pattern with a metal having a chemical activity weaker than Cu, such that the drain electrode is electrically connected to the pixel electrode through the conductive pattern.

In this embodiment, the drain electrode of the driving thin-film transistor is not in direct contact with the pixel electrode. Thus, when the pixel electrode is prepared with ITO and the drain electrode is prepared with a metal such as Cu or Al which is easily oxidized, since the ITO is not in direct contact with the drain electrode, it is capable of preventing from forming an oxide on the surface of the drain electrode, and ensuring the reliability of the connection between the pixel electrode and the drain electrode, thereby improving the display quality of the display device.

Since Cu is easily oxidized when it is in contact with ITO, in order to prevent oxidation of the conductive pattern when it is in contact with the pixel electrode, the conductive pattern is prepared with a metal having a chemical activity weaker than Cu, e.g., it may be prepared with Mo or Ti. Mo and Ti have relatively stable properties, and will not form an oxide when being in contact with ITO.

In one embodiment, an insulating layer is arranged between the drain electrode and the conductive pattern, with the drain electrode being connected to the conductive pattern through a via hole penetrating through the insulating layer, that is, the conductive pattern is arranged in a different layer from that of the drain electrode; or, an insulating layer is arranged between the pixel electrode and the conductive pattern, with the pixel electrode being connected to the conductive pattern through a via hole penetrating through the insulating layer, that is, the conductive pattern is arranged in a different layer from that of the pixel electrode.

Further, an insulating layer is arranged between the drain electrode and the conductive pattern, with the drain electrode being connected to the conductive pattern through a via hole penetrating through the insulating layer; and an insulating layer is arranged between the pixel electrode and the conductive pattern, with the pixel electrode being connected to the conductive pattern through a via hole penetrating through the insulating layer, that is, both the pixel electrode and the drain electrode are arranged in different layers from that of the conductive pattern.

Further, the conductive pattern may be made of a same material and arranged in a same layer as those of other film layer patterns of the display substrate, such that the conductive pattern and other film layer patterns of the display substrate can be simultaneously formed by a single patterning process, and thus a conductive pattern is formed without increasing the number of times of patterning the display substrate.

Further, the conductive pattern may be arranged in the same layer as that of the common electrode line of the display substrate, such that the conductive pattern and the common electrode line of the display substrate may be formed by a single patterning process.

Further, the common electrode line and a data line of the display substrate extend in a same direction, and an orthogonal projection of the common electrode line on a base substrate of the display substrate at least partially overlaps an orthogonal projection of the data line on the base substrate, which may improve the transmittance of the display substrate. Optionally, the orthogonal projection of the common electrode line on the base substrate completely overlaps with the orthogonal projection of the data line on the base substrate.

A common voltage signal is transmitted on the common electrode line. In order to prevent the electrical signal transmitted on the common electrode line from affecting the data voltage signal transmitted on the data line, the distance between the common electrode line and the data line should be relatively far. Optionally, an organic insulating layer is formed between the data line and the common electrode line. The thickness of the organic insulating layer is generally relatively large, such that the distance between the data line and the common electrode line is relatively far. Specifically, the organic insulating layer may have a thickness of 1 μm to 2 μm.

Unless otherwise defined, technical terms or scientific terms used herein have the normal meaning commonly understood by one skilled in the art in the field of the present disclosure. The words “first”, “second”, and the like used in the present disclosure does not denote any order, quantity, or importance, but rather merely serves to distinguish different components. The “including”, “comprising”, and the like used in the present disclosure means that the element or item appeared in front of the word encompasses the element or item and their equivalents listed after the word, and does exclude other elements or items. The word “connected” or “connecting” and the like are not limited to physical or mechanical connections, but may include electrical connections, whether direct or indirect. “On”, “under”, “left”, “right” and the like are only used to represent relative positional relationships, and when the absolute position of the described object is changed, the relative positional relationship may also be changed, accordingly.

It will be understood that when an element, such as a layer, film, region, or substrate, is referred to as being “on” or “under” another element, the element may be directly “on” or “under” another element, or there may be an intermediate element.

The above description is alternative embodiments of the present disclosure. It should be noted that one skilled in the art would make several improvements and substitutions without departing from the principles of the present disclosure. These improvements and modifications should also be regarded as the protection scope of the present disclosure.

What is claimed is:

1. A display substrate, comprising a driving thin-film transistor and a pixel electrode, wherein a drain electrode of the driving thin-film transistor is electrically connected to the pixel electrode through a conductive pattern made of a metal having a chemical activity weaker than Cu.

2. The display substrate of claim 1, wherein the drain electrode is not in direct contact with the pixel electrode.

3. The display substrate of claim 1, wherein
an insulating layer is arranged between the drain electrode and the conductive pattern, with the drain electrode being connected to the conductive pattern through a via hole penetrating through the insulating layer.

4. The display substrate of claim 1, wherein an insulating layer is arranged between the pixel electrode and the conductive pattern, with the pixel electrode being connected to the conductive pattern through a via hole penetrating through the insulating layer.

5. The display substrate of claim 1, wherein an insulating layer is arranged between the drain electrode and the conductive pattern, with the drain electrode being connected to the conductive pattern through a via hole penetrating through the insulating layer, and
an insulating layer is arranged between the pixel electrode and the conductive pattern, with the pixel electrode being connected to the conductive pattern through a via hole penetrating through the insulating layer.

6. The display substrate of claim 1, wherein the conductive pattern is made of Mo or Ti.

7. The display substrate of claim 1, wherein the conductive pattern and a common electrode line of the display substrate are made of a same material and arranged in a same layer.

8. The display substrate of claim 7, wherein the common electrode line and a data line of the display substrate extend in a same direction and an orthogonal projection of the common electrode line on a base substrate of the display substrate at least partially overlaps an orthogonal projection of the data line on the base substrate.

9. The display substrate of claim 8, wherein an organic insulating layer is arranged between the data line and the common electrode line.

10. The display substrate of claim 9, wherein the organic insulating layer has a thickness of 1 μm to 2 μm.

11. The display substrate of claim 8, wherein a passivation layer and an overcoat are arranged between the common electrode line and the data line.

12. The display substrate of claim 11, wherein the overcoat is made of an organic resin.

13. A display device comprising the display substrate of claim 1.

14. A method for manufacturing a display substrate comprising a driving thin-film transistor and a pixel electrode, comprising:
forming a drain electrode of the driving thin-film transistor and the pixel electrode; and
forming a conductive pattern with a metal having a chemical activity weaker than Cu, such that the drain electrode is electrically connected to the pixel electrode through the conductive pattern.

15. The method of claim 14, wherein
the conductive pattern and a common electrode line of the display substrate are formed by a single patterning process.

16. The method of claim 14, wherein the drain electrode is not in direct contact with the pixel electrode.

17. The method of claim 14, wherein the conductive pattern is made of Mo or Ti.

18. The method of claim 14, wherein the conductive pattern and a common electrode line of the display substrate are made of a same material and arranged in a same layer.

19. The method of claim 17, wherein an organic insulating layer is arranged between a data line of the display substrate and the common electrode line.

20. The method of claim 18, wherein the organic insulating layer has a thickness of 1 μm to 2 μm.
